(19) United States
(12) Patent Application Publication
(10) Pub. No.: US 2021/0295920 A1
(43) Pub. Date: Sep. 23, 2021

(54) SEMICONDUCTOR STORAGE DEVICE AND CONTROL METHOD OF SEMICONDUCTOR STORAGE DEVICE

(71) Applicants: Kabushiki Kaisha Toshiba, Tokyo (JP); Toshiba Electronic Devices & Storage Corporation, Tokyo (JP)

(72) Inventor: Masaki Ichikawa, Fujisawa Kanagawa (JP)

(21) Appl. No.: 17/015,704

(22) Filed: Sep. 9, 2020

(30) Foreign Application Priority Data
Mar. 23, 2020 (JP) 2020-051782

(51) Int. Cl. G11C 16/10; G11C 16/26; G11C 16/08; G11C 16/24; G11C 16/04

(52) U.S. Cl. CPC G11C 16/10; G11C 16/26; G11C 16/0433; G11C 16/24; G11C 16/08

(57) ABSTRACT

A semiconductor storage device according to the present embodiment includes a plurality of memory cell arrays, a plurality of block selectors, and a controller. The memory cell arrays each include a plurality of subblocks connected to each other via common word lines, and include memory cells at respective intersections between the word lines and bit lines provided in each subblock. The block selectors each include switching elements connected to bit lines in a corresponding one of the subblocks at one ends and to a corresponding sense amplifier at the other ends. The controller maintains, in a case where data is read out from one subblock in a same memory cell array and thereafter data is read out from another subblock in the same memory cell array, switching elements in a block selector corresponding to the one subblock in a conductive state.

### CROSS-REFERENCE TO RELATED APPLICATIONS

This application is based upon and claims the benefit of priority from the prior Japanese Patent Application No. 2020-051782, filed on Mar. 23, 2020, the entire contents of which are incorporated herein by reference.

### FIELD

Embodiments of the present invention relate to a semiconductor storage device and a control method of a semiconductor storage device.

### BACKGROUND

In general, a bit line capacity is reduced in order to increase a reading speed in a semiconductor storage device. One of methods for reducing the bit line capacity is to divide a memory array into a plurality of memory cell arrays and reduce a block capacity. In this block division method, when reading is carried out for a memory cell, a memory cell array including the read target memory cell is selected. When this block division method is employed, a memory-cell-array selection signal that selects a memory cell array is required in addition to usual selection signals for selecting a column and a row. This memory-cell-array selection signal drives switching elements corresponding to all columns in the memory cell array, and therefore a power load becomes large.

Therefore, the control range of switching elements in a row direction of each memory cell array is divided in some cases. In this method of dividing the control range of switching elements, a peak current of a current that drives switching elements is reduced. However, when reading is carried out for memory cells located in different control ranges in the same memory cell array, switching elements in the same memory cell array are driven, causing increase of current consumption.

### BRIEF DESCRIPTION OF THE DRAWINGS

FIG. 1 is a block diagram of a semiconductor storage device;

FIG. 2 is a diagram illustrating an example of an equivalent circuit of portions of a memory cell array, a row decoder, and a block selector;

FIG. 3 is a diagram illustrating a configuration example of a logic circuit according to an embodiment of the present invention;

FIG. 4 is a diagram illustrating truth values of a flip-flop;

FIG. 5 is a diagram illustrating a configuration example of the logic circuit;

FIG. 6 is a diagram illustrating signal examples output by a logic circuit on a lower-order side when a read position is moved;

FIG. 7 is a diagram illustrating signal examples of a logic circuit on a higher-order side when a read position is moved;

FIG. 8 is a diagram illustrating a configuration example of the logic circuit on a lower-order side in a first comparative example;

FIG. 9 is a diagram illustrating a configuration example of the logic circuit on a higher-order side in the first comparative example;

FIG. 10 is a diagram illustrating truth values of AND circuits;

FIG. 11 is a diagram illustrating a configuration example of a second comparative example;

FIG. 12 is a diagram illustrating an example of a read operation of the semiconductor storage device;

FIG. 13 is an explanatory diagram of an operation example in reading with transition between subblocks; and

FIG. 14 is an explanatory diagram of an operation example in a mode of reading with transition between blocks.

### DETAILED DESCRIPTION

A semiconductor storage device and a control method of a semiconductor storage device according to embodiments of the present invention will now be explained in detail with reference to the accompanying drawings. The embodiments described below are only examples of the embodiments of the present invention and it is not to be understood that the present invention is limited to these embodiments. In the drawings referred to in the embodiments, same parts or parts having identical functions are denoted by like or similar reference characters and there is a case where redundant explanations thereof are omitted. Further, for convenience of explanation, there are cases where dimensional ratios of the parts in the drawings are different from those of actual products and some part of configurations is omitted from the drawings.

### First Embodiment

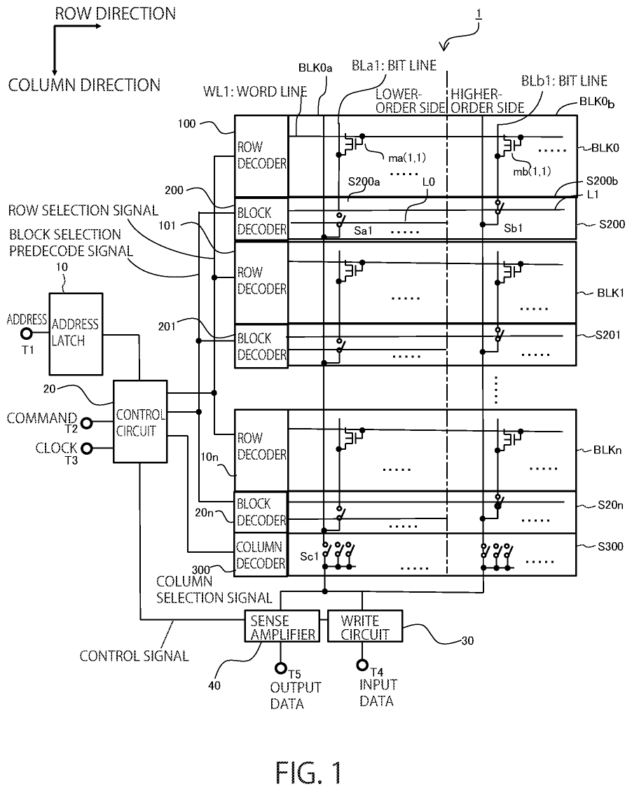

FIG. 1 is a block diagram of a semiconductor storage device 1. As illustrated in FIG. 1, the semiconductor storage device 1 can store therein data by a plurality of memory cells ma and mb, and includes an address latch 10, a control circuit 20, a write circuit 30, a sense amplifier 40, a plurality of memory cell arrays BLK0 to BLKn, row decoders 100 to 10n, a plurality of block selectors S200 to S20n, block decoders 200 to 20n, a column selector S300, and a column decoder 300. The semiconductor storage device 1 is arranged on a SOI (Silicon On Insulator) substrate, for example. When the semiconductor storage device 1 is arranged on the SOI (Silicon On Insulator) substrate, it is possible to reduce a parasitic capacitance of a transistor. Therefore, this arrangement is advantageous in increasing an operating speed and reducing power consumption.

Further, a plurality of bit lines BLa1 and BLb1, a plurality of word lines L0 and L1, and a plurality of terminals T1 to T5 are illustrated in FIG. 1. The block decoders 200 to 20n according to the present embodiment correspond to a controller. In FIG. 1, one word line WL1, the bit lines BLa1 and BLb1, and the memory cells ma(1, 1) and mb(1, 1) are illustrated, and the rest is omitted.

The address latch 10 latches an address signal input from the address terminal T1. The address latch 10 then supplies a signal including the latched address to the control circuit 20.

The control circuit 20 generates a row selection signal based on a command input from the command decoder terminal T2 and information on a row address supplied from the address latch 10, and supplies the row selection signal to the row decoders 100 to 10n. Also, the control circuit 20 generates a block (BLK) selection predecode signal based on the command input from the command decoder terminal T2 and information on a block address supplied from the address latch 10, and supplies the block selection predecode signal to the block decoders 200 to 20n. Similarly, the control circuit 20 generates a column selection signal based on the command input from the command decoder terminal T2 and information on a column address supplied from the address latch 10, and supplies the column selection signal to the column decoder 300.

Further, the control circuit 20 generates an internal clock signal based on a clock input from the clock terminal T3 and supplies the internal clock signal to the write circuit 30 and the sense amplifier 40. Furthermore, the control circuit 20 controls the write circuit 30 and the sense amplifier 40 based on the command input from the command decoder terminal T2.

The write circuit 30 takes in input data supplied to the data input terminal T4 in synchronization with an internal clock in a write operation, and outputs the input data to any of the memory cell arrays BLK0 to BLKn via the column selector S300.

The sense amplifier 40 amplifies read data read from any of the memory cell arrays BLK0 to BLKn via the column selector S300 in a read operation, and outputs the read data as output data from the data output terminal T5. In at least one of the write operation and the read operation, access may be made to a plurality of the memory cell arrays BLK0 to BLKn simultaneously in a test mode, for example.

In each of the memory cell arrays BLK0 to BLKn, a plurality of word lines WL and a plurality of bit lines BL are formed to intersect with each other. The memory cell arrays BLK0 to BLKn are divided into lower-order subblocks BLK0a to BLKna on the lower-order side and higher-order subblocks BLK0b to BLKnb on the higher-order side. In a case where control ranges in the row direction of switching elements Sa1 to Sa16 and switching elements Sb1 to Sb16 described later can be separated from each other, each control range is called a subblock in the present embodiment. Therefore, the subblocks are not necessarily separated from each other physically, as long as the switching elements Sa1 to Sa16 and the switching elements Sb1 to Sb16 can be grouped and be controlled on a group-by-group basis. Further, in the present embodiment, it is assumed that the subblocks BLK0a to BLKna are lower-order subblocks and the subblocks BLK0b to BLKnb are higher-order subblocks for the sake of convenience of descriptions. It may be assumed that the subblocks BLK0a to BLKna are higher-order subblocks and the subblocks BLK0b to BLKnb are lower-order subblocks.

In the lower-order subblock BLK0a, a plurality of memory cells ma(1, 1) to ma(16, 16) are arranged to correspond to respective intersections between word lines WL1 to WL16 and bit lines BLa1 to BLa16. The word lines WL1 to WL16 are common lines that are common to the lower-order subblock BLK0a on the lower-order side and the higher-order subblock BLK0b on the higher-order side.

The memory cells ma(1, 1) to ma(16, 16) are configured by, for example, N-channel transistors. For example, a source of each transistor is grounded and a gate is connected to a corresponding one of the word lines WL1 to WL16. A drain is connected to a corresponding one of the bit lines BLa1 to BLa16. The bit lines BLa1 to BLa16 are connected to the sense amplifier 40 via a corresponding block selector S200a and the column selector S300.

Similarly, in the higher-order subblock BLK0b, a plurality of memory cells mb(1, 1) to mb(16, 16) are arranged to correspond to respective intersections between the word lines WL1 to WL16 and bit lines BLb1 to BLb16. The memory cells mb(1, 1) to mb(16, 16) are configured by, for example, N-channel transistors. For example, a source of each transistor is grounded and a gate is connected to a corresponding one of the word lines WL. A drain is connected to a corresponding one of the bit lines BLb1 to BLb16. In FIG. 1, one word line WL1, one bit line BLb1, and one memory cell mb(1, 1) are illustrated, and the rest is omitted.

The bit lines BLb1 to BLb16 are connected to the sense amplifier 40 via a corresponding block selector S200b and the column selector S300. Although descriptions are made on the two subblocks BLK0a and BLK0b and the memory cells ma(1, 1) to ma(16, 16) and mb(1, 1) to mb(16, 16) for simplifying descriptions in the present embodiment, the number of subblocks and the number of memory cells are not limited thereto. For example, the number of subblocks may be any number, for example, 100 as long as it is equal to or larger than two. Further, the number of memory cells in each subblock is not limited to 16×16. For example, the number of memory cells may be 1024×1024.

The row decoders 100 to 10n are arranged to correspond to the memory cell arrays BLK0 to BLKn, respectively. Each of the row decoders 100 to 10n is connected to the word lines WL1 to WL16 in a corresponding one of the memory cell arrays BLK0 to BLKn. Each of the row decoders 100 to 10n performs an operation of selecting one of the word lines WL1 to WL16 or an operation of not selecting any word line in accordance with a row selection signal. That is, the word line WL to which a memory cell m selected as a read target memory cell is connected is selected, and an ON signal is supplied thereto. Accordingly, transistors connected to the selected word line WL become a conductive state (ON). Meanwhile, an OFF signal is supplied to transistors connected to the unselected word line WL, so that those transistors become a non-conductive state (OFF).

The block selectors S200 to S20n are arranged to correspond to the memory cell arrays BLK0 to BLKn, respectively. The block selectors S200 to S20n include a plurality of block selectors S200a to S20na on the lower-order side and a plurality of block selectors S200b to S20nb on the higher-order side. That is, the block selectors S200a to S20na correspond to the lower-order subblocks BLK0a to BLKna on the lower-order side, respectively, and the block selectors S200b to S20nb correspond to the higher-order subblocks BLK0b to BLKnb on the higher-order side, respectively.

The block selectors S200a to S20na and the block selectors S200b to S20nb include the switching elements Sa1 to Sa16 respectively connected to the bit lines BL in the corresponding lower-order subblocks BLK0a to BLKna and the switching elements Sb1 to Sb16 respectively connected to the bit lines BL in the corresponding higher-order subblocks BLK0b to BLKnb.

The switching elements Sa1 to Sa16 are connected to the corresponding bit lines BLa1 to BLa16 at one ends, respectively, and to the sense amplifier 40 via the column selector S300 at the other ends. Similarly, the switching elements Sb1 to Sb16 are connected to the corresponding bit lines BLb1 to BLb16 at one ends, respectively, and to the sense amplifier 40 via the column selector S300 at the other ends. In FIG. 1, only the switching elements Sa1 and Sb1 are illustrated, and other switching elements are omitted. The switching elements Sa1 to Sa16 are connected to a block control line L0 and the switching elements Sb1 to Sb16 are connected to a block control line L1. When the block control line L0 is selected and an ON signal is supplied, the switching elements Sa1 to Sa16 become a conductive state (ON). Meanwhile, when an OFF signal is supplied, the switching elements Sa1 to Sa16 become a non-conductive state (OFF). Similarly, when the block control line L1 is selected and an ON signal is supplied, the switching elements Sb1 to Sb16 become a conductive state (ON). Meanwhile, when an OFF signal is supplied, the switching elements Sb1 to Sb16 become a non-conductive state (OFF).

The block decoders 200 to 20n are arranged to correspond to the block selectors S200 to S20n, respectively. That is, the block decoders 200 to 20n are arranged to correspond to the memory cell arrays BLK0 to BLKn, respectively.

Each of the block decoders 200 to 20n is connected to the block control lines L0 and L1 in a corresponding one of the block selectors S200 to S20n. Each of the block decoders 200 to 20n selects either one of the block control lines L0 and L1 in accordance with a block selection predecode signal. Details of the block decoders 200 to 20n will be described later.

The column selector S300 includes a plurality of switching elements Sc1 to Sc36 connected to the other ends of the switching elements Sa1 to Sa16 and the switching elements Sb1 to Sb16 in the block decoders 200 to 20n, for example. FIG. 1 illustrates the switching element Sc1 only. The other ends of the switching elements Sc1 to Sc36 are connected to the write circuit 30 and the sense amplifier 40.

The column decoder 300 causes one of the switching elements Sc1 to Sc36, which corresponds to the bit line BL to be selected, to be a conductive state in accordance with a column selection signal.

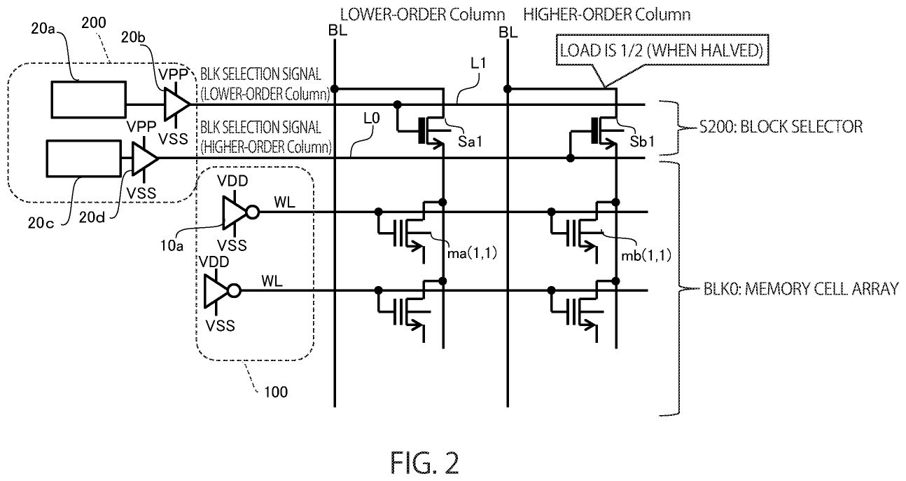

FIG. 2 is a diagram illustrating an example of an equivalent circuit of portions of the memory cell array BLK0, the row decoder 100, and the block selector S200. As illustrated in FIG. 2, the block decoder 200 includes logic circuits 20a and 20c and buffers 20b and 20d.

The logic circuit 20a outputs an ON signal or an OFF signal in accordance with a block selection predecode signal. Similarly, the logic circuit 20c outputs an ON signal or an OFF signal in accordance with the block selection predecode signal. Details of the logic circuits 20a and 20c will be described later. The switching elements Sa1 and Sb1 are NMOS transistors, for example.

The buffer 20b is charged to VPP in a case where the logic circuit 20a outputs an ON signal having a value 1. Accordingly, the switching element Sa1 becomes a conductive state. Also, the selected switching element Sa1 is charged to VPP.

Meanwhile, the buffer 20b is charged to VSS in a case where the logic circuit 20a outputs an OFF signal having a value 0. Accordingly, the switching element Sa1 becomes a non-conductive state. The switching element Sa1 is also charged to VSS. VSS is a voltage lower than VPP, and therefore power is discharged.

Similarly, the buffer 20d is charged to VPP in a case where the logic circuit 20c outputs an ON signal having a value 1. Accordingly, the switching element Sb1 becomes a conductive state. Also, the selected switching element Sb1 is charged to VPP. Meanwhile, the buffer 20d is charged to VSS in a case where the logic circuit 20c outputs an OFF signal having a value 0. Accordingly, the switching element Sb1 becomes a non-conductive state. The switching element Sb1 is also charged to VSS. VSS is a voltage lower than VPP, and therefore power is discharged.

A buffer 10a sets the word line WL to VDD when an ON signal is input, so that the memory cells ma(1, 1) and mb(1, 1) become a conductive state. Meanwhile, the buffer 10a sets the word line WL to VSS when an OFF signal is output, so that the memory cells ma(1, 1) and mb(1, 1) become a non-conductive state.

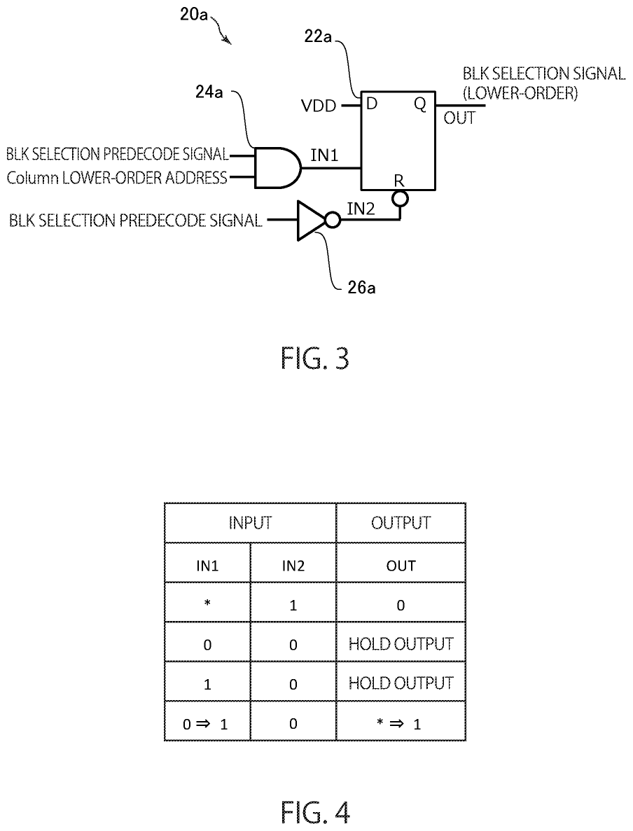

FIG. 3 is a diagram illustrating a configuration example of the logic circuit 20a according to the present embodiment. As illustrated in FIG. 3, the logic circuit 20a includes a flip-flop 22a, an AND circuit 24a, and an inverter circuit 26a.

An operation of the flip-flop 22a is described with reference to FIG. 4. FIG. 4 is a diagram illustrating truth values of the flip-flop 22a. In FIG. 4, IN1 represents input to a CLK terminal and IN2 represents input to an R terminal. As illustrated in FIG. 4, when IN2 is 1, the flip-flop 22a outputs 0 irrespective of IN1. That is, when IN2 is 1, the flip-flop 22a resets its output. When IN1 is 0 and IN2 is 0, the flip-flop 22a holds its output. Further, when IN1 is 1 and IN2 is 0, the flip-flop 22a holds its output. When IN1 is changed from 0 to 1 and IN2 is 0, the output becomes 0.

Referring back to FIG. 3, the output of the AND circuit 24a is IN1 and the output of the inverter circuit 26a is IN2. That is, the AND circuit 24a outputs 1 in a case where a BLK selection predecode signal is 1 and a column lower-order address is 1, and outputs 0 in other cases. The inverter circuit 26a outputs 0 in a case where the BLK selection predecode signal is 1, and outputs 1 in a case where the BLK selection predecode signal is 0. The BLK selection predecode signal is 1 when selection is to be made, and 0 when no selection is to be made. Similarly, the column lower-order address is 1 when selection is to be made, and 0 when no selection is to be made.

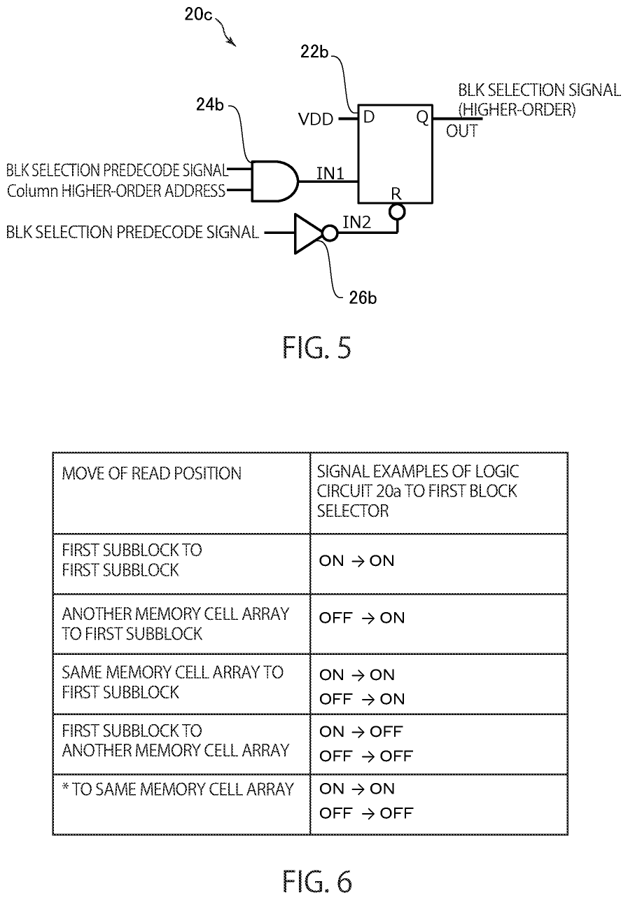

FIG. 5 is a diagram illustrating a configuration example of the logic circuit 20c according to the present application. As illustrated in FIG. 5, the logic circuit 20c has an equivalent configuration to the logic circuit 20a and includes a flip-flop 22b, an AND circuit 24b, and an inverter circuit 26b. That is, the output of the AND circuit 24b is IN1 and the output of the inverter circuit 26b is IN2. That is, the AND circuit 24b outputs 1 in a case where a BLK selection predecode signal is 1 and a column higher-order address is 1, and outputs 0 in other cases. The inverter circuit 26b outputs 0 in a case where the BLK selection predecode signal is 1, and outputs 1 in a case where the BLK selection predecode signal is 0. The column higher-order address is 1 when selection is to be made, and 0 when no selection is to be made.

FIG. 6 is a diagram illustrating signal examples output by the logic circuit 20a when a read position is moved. A first block selector corresponds to the block selector S200a, for example, and a first subblock corresponds to the lower-order subblock BLK0a, for example.

An ON signal corresponds to 1 and causes the switching elements Sa1 to Sa16 to be in a conductive state. An OFF signal corresponds to 0 and causes the switching elements Sa1 to Sa16 to be in a non-conductive state. “Another memory cell array” means a memory cell array other than the memory cell array BLK0. For example, “another memory cell array” with respect to the memory cell array BLK0 means the memory cell arrays BLK1 to BLKn. Further, “the same memory cell array” means another subblock in the memory cell array BLK0. For example, “the same memory cell array” with respect to the subblock BLK0a corresponds to the other subblock BLK0b in the memory cell array BLK0. “*” means any subblock. For example, “*” with respect to the subblock BLK0a means all subblocks other than the subblock BLK0a. Therefore, the description “* to the same memory cell array” means move from any of all the subblocks other than the subblock BLK0a to the other subblock BLK0b in the memory cell array BLK0, for example.

An operation example in FIG. 6 is explained with reference to FIGS. 3 and 4. As represented in the first row in FIG. 4, when IN2 is 1, the output is 0. When IN2 is 0, the memory cell array BLK0 including the subblock BLK0a is not selected. This state corresponds to a state of “another memory cell array” in the second row and a state of “another memory cell array” in the fourth row in FIG. 6. In this case, irrespective of the preceding state, the logic circuit 20a outputs an OFF signal (value 0).

As illustrated in FIG. 4, when IN1 is 0 and IN2 is 0, the logic circuit 20a holds its output. With reference to FIG. 3, when IN1 is 0 and IN2 is 0, the memory cell array BLK0 including the first subblock BLK0a is selected but the first subblock BLK0a is not selected. This state corresponds to a state of “the same memory cell array” in the third and fifth rows in FIG. 6. That is, in the move operation of the fifth row in FIG. 6, the logic circuit 20a maintains its output signal to be an ON signal in a case where the preceding output signal is the ON signal, and maintains its output signal to be an OFF signal in a case where the preceding output signal is the OFF signal.

As illustrated in FIG. 4, when IN1 is 1 and IN2 is 0, the logic circuit 20a holds its output. With reference to FIG. 3, this case corresponds to a case where the first subblock BLK0a is selected. In this case, when IN1 in the preceding state is also 1, a corresponding operation is the move operation of the first row in FIG. 6. Because this case corresponds to a case where the preceding output signal of the logic circuit 20a is an ON signal, the output signal is maintained to be the ON signal.

As illustrated in FIG. 4, when IN1 is changed from 0 to 1 and IN2 is 0, the logic circuit 20a outputs an ON signal. With reference to FIG. 3, this case corresponds to a case where the first subblock BLK0a that has not been selected is selected. This case corresponds to the move operation of the second row and the move operation of the third row in FIG. 6. In this case, irrespective of the preceding signal, the logic circuit 20a outputs an ON signal.

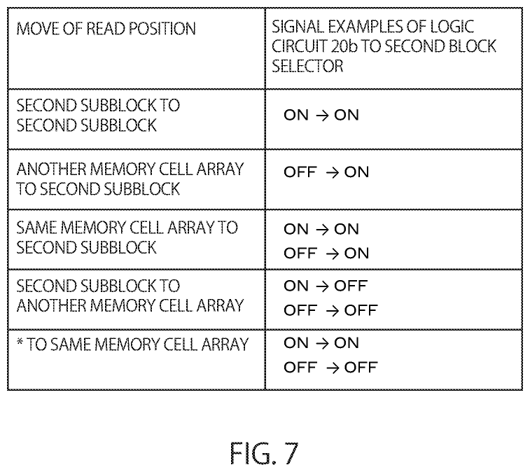

FIG. 7 is a diagram illustrating signal examples of the logic circuit 20c when a read position is moved. A second block selector corresponds to the block selector S200b, for example, and a second subblock corresponds to the higher-order subblock BLK0b, for example. An ON signal corresponds to 1 and causes the switching elements Sb1 to Sb16 to be in a conductive state. An OFF signal corresponds to 0 and “another memory cell array” that means a non-conductive state means a memory cell array other than the memory cell array BLK0. Further, “the same memory cell array” means another subblock in the memory cell array BLK0. “*” means any subblock. As illustrated in FIG. 7, the logic circuit 20c also outputs an equivalent signal to that of the logic circuit 20a.

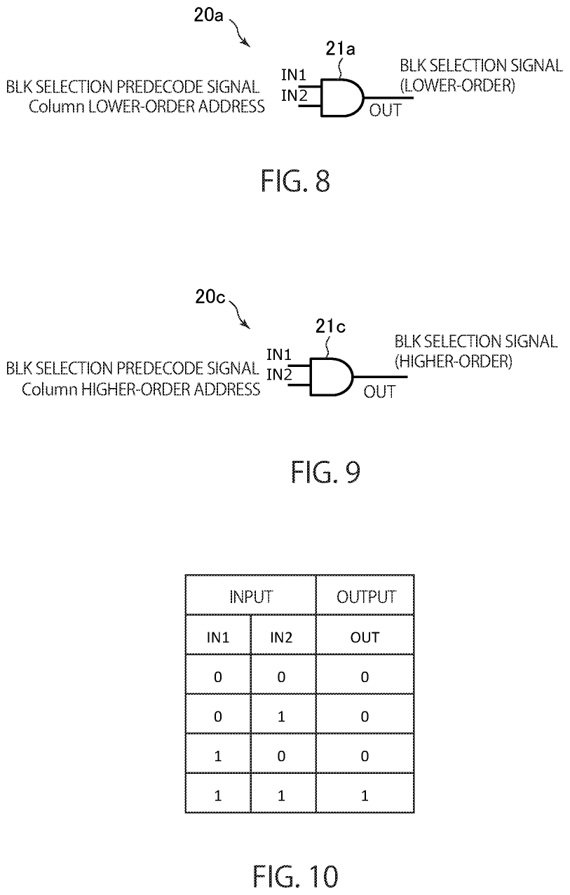

FIG. 8 is a diagram illustrating a configuration example of the logic circuit 20a in a first comparative example. As illustrated in FIG. 8, the logic circuit 20a in the first comparative example includes an AND circuit 21a. Similarly, FIG. 9 is a diagram illustrating a configuration example of the logic circuit 20c in the first comparative example. As illustrated in FIG. 9, the logic circuit 20c includes an AND circuit 21c. FIG. 10 is a diagram illustrating truth values of the AND circuits 21a and 21c.

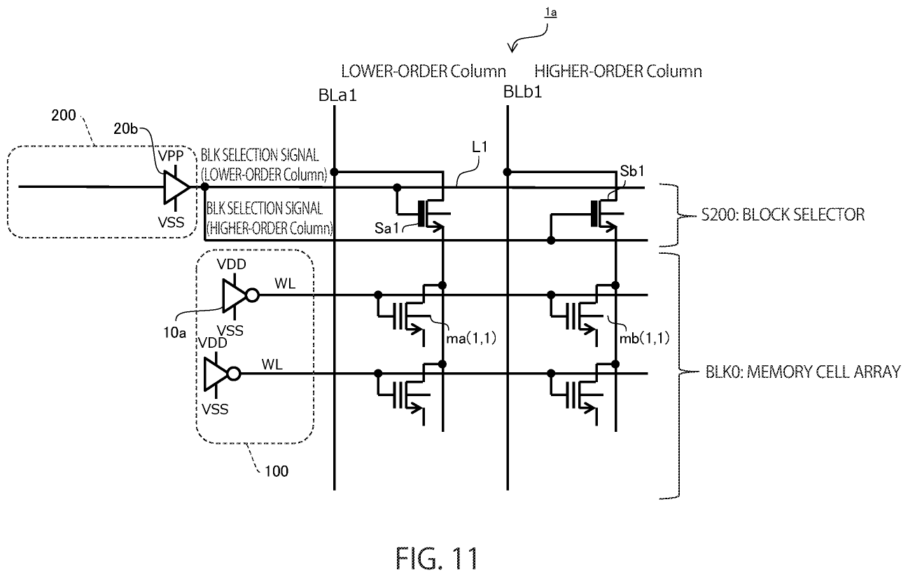

FIG. 11 is a diagram illustrating a configuration example of a second comparative example. In this example, a conductive state (ON) and a non-conductive state (OFF) of the switching elements Sa1 to Sa16 and the switching elements Sb1 to Sb16 in the block selector S200 are controlled only with the control line L1.

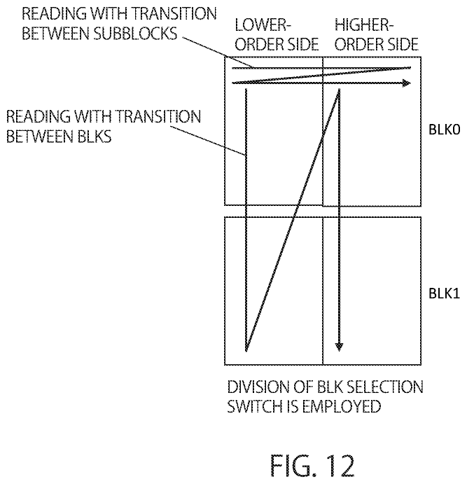

FIG. 12 is a diagram illustrating an example of a read operation of the semiconductor storage device 1. As illustrated in FIG. 12, data reading while a column position is changed in the same row in the same memory cell array BLK0 is called reading with transition between subblocks. Further, data reading from any ones of the memory cell arrays BLK0 to BLKn while a row position is changed in the same column is called reading with transition between blocks (BLK).

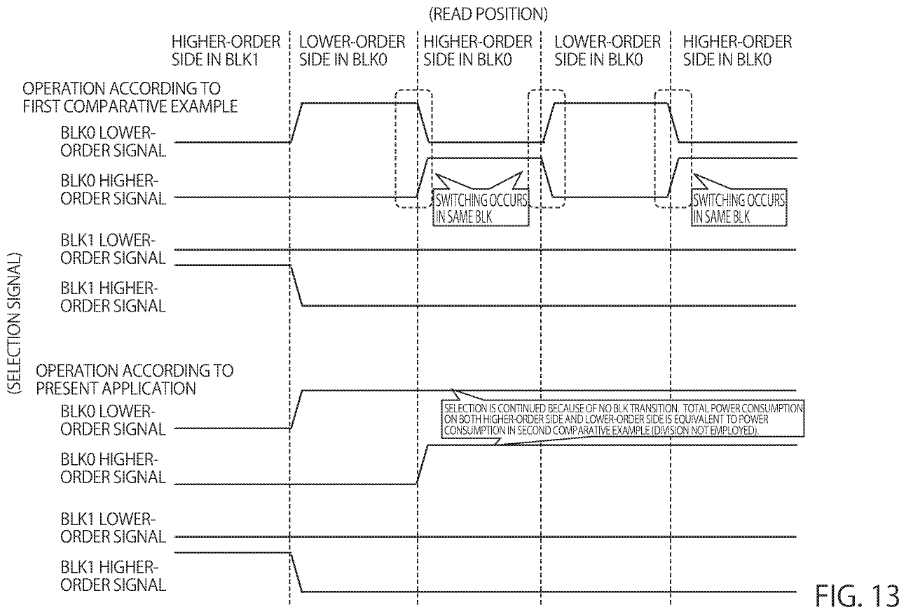

FIG. 13 is an explanatory diagram of an operation example in reading with transition between subblocks of each of the block selectors S200 in the first comparative example and the semiconductor storage device 1 according to the present embodiment. The vertical axis represents signal levels of a BLK0 lower-order signal, a BLK0 higher-order signal, a BLK1 lower-order signal, and a BLK1 higher-order signal in the first comparative example from top. The upper level of each signal represents an ON signal, and the lower level represents an OFF signal. That is, the ON signal corresponds to 1 and the OFF signal corresponds to 0.

Below the signals listed above, a BLK0 lower-order signal, a BLK0 higher-order signal, a BLK1 lower-order signal, and a BLK1 higher-order signal in the semiconductor storage device 1 according to the present embodiment are illustrated from top. An ON signal corresponds to 1 and an OFF signal corresponds to 0.

That is, with reference to FIG. 1, the BLK0 lower-order signal is a signal supplied to the line L0 of the block decoder 200, and the BLK0 higher-order signal is a signal supplied to the line L1 of the block decoder 200. Similarly, the BLK1 lower-order signal is a signal supplied to the line L0 of the block decoder 201, and the BLK1 higher-order signal is a signal supplied to the line L1 of the block decoder 201.

The horizontal axis represents a time. A higher-order side in BLK1 represents that a read position is in higher-order columns of the memory cell array BLK1, that is, in the subblock BLK1b. A lower-order side in BLK0 represents that a read position is in lower-order columns of the memory cell array BLK0, that is, in the subblock BLK0a. A higher-order side in BLK0 represents that a read position is in higher-order columns of the memory cell array BLK0, that is, in the subblock BLK0b. Further, a lower-order side in BLK1 represents that a read position is in lower-order columns of the memory cell array BLK1, that is, in the subblock BLK1a.

In the first comparative example, when a read position is in the higher-order side in BLK1, the BLK0 lower-order signal is 0 because a BLK selection predecode signal is 0. Similarly, the BLK0 higher-order signal is 0 because the BLK selection predecode signal is 0.

Further, the BLK1 lower-order signal 0 because a column lower-order address signal is 0. Meanwhile, the BLK1 higher-order signal is 1 because the BLK selection predecode signal is 1 and a column higher-order address signal is 1. That is, in the first comparative example, only the BLK1 higher-order signal corresponding to a case where the read position is in higher-order columns of the memory cell array BLK1 is 1, and the other signals are 0.

Accordingly, as illustrated in FIG. 13, in the first comparative example, every time a read position is moved to the lower-order side in BLK0, the higher-order side in BLK0, the lower-order side in BLK0, and the higher-order side in BLK0 even in the same memory cell array BLK0, a conductive state (ON) and a non-conductive state (OFF) of the switching elements Sa1 to Sa16 and the switching elements Sb1 to Sb16 in the block selector S200 are switched with each other. Every time switching occurs, application of power and discharge are repeated on the higher-order column side in the memory cell array BLK0 and the lower-order column side, so that power consumption becomes large. That is, power consumption in reading with transition between subblocks is increased.

Meanwhile, in an operation according to the present application, in a case where IN1 is 1, the output of the logic circuit 20a is maintained when IN2 is 0, as described above. Further, in a case where IN1 is 0, the output of the logic circuit 20a is maintained when IN2 is 0. Therefore, once IN1 becomes 1 and OUT becomes 1, OUT is maintained to be 1 until block (BLK) transition occurs, that is, IN2 is changed to 1, even when IN1 becomes 0 before that transition. Therefore, even if a read position is moved in the same memory cell array BLK0 to the lower-order side in BLK0, the higher-order side in BLK0, the lower-order side in BLK0, and the higher-order side in BLK0, the switching elements Sa1 to Sa16 and the switching elements Sb1 to Sb16 in the block selector S200 are maintained in a conductive state (ON). Accordingly, power consumption in reading with transition between subblocks is reduced.

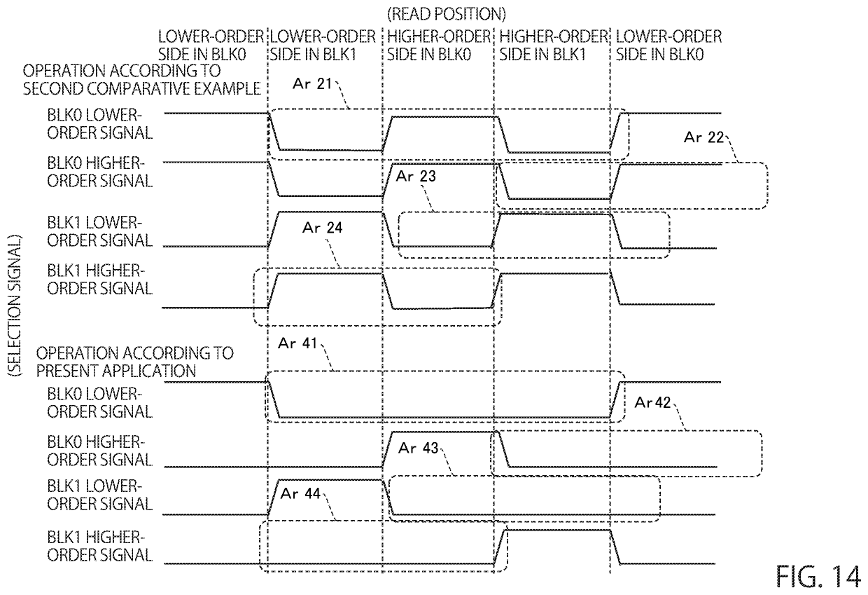

FIG. 14 is an explanatory diagram of an operation example in a mode of reading with transition between blocks of each of the block selectors S200 in the second comparative example and the semiconductor storage device 1 according to the present application. The vertical axis represents signal levels of a BLK0 lower-order signal, a BLK0 higher-order signal, a BLK1 lower-order signal, and a BLK1 higher-order signal in the second comparative example from top, where an ON signal is represented by 1 and an OFF signal is represented by 0. Below the signals listed above, a BLK0 lower-order signal, a BLK0 higher-order signal, a BLK1 lower-order signal, and a BLK1 higher-order signal in the semiconductor storage device 1 according to the present application are illustrated from top. An ON signal corresponds to 1 and an OFF signal corresponds to 0.

The horizontal axis represents a time. A read position is changed in the order of a lower-order side in BLK0, a lower-order side in BLK1, a higher-order side in BLK0, a higher-order side in BLK1, and the lower-order side in BLK0 with time. The meanings of the lower-order side in BLK0, the lower-order side in BLK1, the higher-order side in BLK0, the higher-order side in BLK1, and the lower-order side in BLK0 are identical to those in FIG. 13.

In the second comparative example, when a selected memory cell array is changed from the memory cell array BLK0 to the memory cell array BLK1, the BLK0 lower-order signal and the BLK0 higher-order signal are changed from ON to OFF. Meanwhile, the BLK1 lower-order signal and the BLK1 higher-order signal are changed from OFF to ON. Similarly, when a selected memory cell array is changed from the memory cell array BLK1 to the memory cell array BLK0, the BLK0 lower-order signal and the BLK0 higher-order signal are changed from OFF to ON. Meanwhile, the BLK1 lower-order signal and the BLK1 higher-order signal are changed from ON to OFF. Accordingly, all the switching elements Sa1 to Sa16 and the switching elements Sb1 to Sb16 in the block selector S200 are driven to be placed in the same state as each other, so that power consumption is increased.

On the other hand, according to the present application, in the operation in the mode of reading with transition between blocks of the semiconductor storage device 1, the preceding signal is maintained when another subblock in the same memory cell array BLK0 is selected. Therefore, the operation has regions in which the OFF signal is maintained, as represented by regions Ar41 to Ar44 respectively corresponding to regions Ar21 to Ar24 in the second comparative example. Accordingly, in the operation in the mode of reading with transition between blocks, power consumption can be reduced as compared with that in the second comparative example.

As described above, according to the present embodiment, in a case where data is read out from one subblock BLK0a in the same memory cell array BLK0 and thereafter data is read out from the other subblock BLK0b in the same memory cell array BLK0, the block decoder 200 executes control of maintaining the switching elements Sa1 to Sa16 in the block selector S200a corresponding to the one subblock BLK0a in a conductive state. Accordingly, in reading with transition between subblocks in which a read position is changed in the same memory cell array BLK0, operations of turning on and off of the switching elements Sa1 to Sa16 are reduced, so that power consumption is reduced more.

Further, in a case where data is read out from one subblock BLK0a in the memory cell array BLK0, the block decoder 200 maintains the switching elements Sb1 to Sb16 in the block selector S200b corresponding to the other subblock BLK0b in the same memory cell array BLK0 in a non-conductive state, if those switching elements Sb1 to Sb16 are already in a non-conductive state. Accordingly, the switching elements Sa1 to Sa16 are maintained to be in a non-conductive state also in a case where reading with transition between blocks is performed next, and therefore operations of turning on and off of the switching elements Sa1 to Sa16 are reduced, so that power consumption is reduced more. Further, also in reading with transition between subblocks in which a read position is changed in the same memory cell array BLK0, in a case where further another subblock BLK is selected, operations of turning on and off of the switching elements Sa1 to Sa16 are reduced, so that power consumption is reduced more.

Furthermore, in a case where the switching elements Sa1 to Sa16 and the switching elements Sb1 to Sb16 of all the block selectors S200a and S200b corresponding to the subblocks BLK0a and BLK0b in the same memory cell array BLK0 are in a non-conductive state and data is read out via one block selector S200a of all the block selectors S200a and S200b, the block decoder 200 causes only the switching elements Sa1 to Sa16 in the one block selector S200a to be in a conductive state. Accordingly, because only the switching elements Sa1 to Sa16 in the one block selector S200a that performs reading in a mode of reading with transition between blocks are caused to be in a conductive state, power consumption is reduced more as compared with a case of causing all the switching elements Sa1 to Sa16 and Sb1 to Sb16 to be in a conductive state.

Further, when reading out data from the other memory cell array BLK1, the block decoder 200 causes the switching elements Sa1 to Sa16 that are in a conductive state in all the block selectors S200a and S200b corresponding to the subblocks BLK0a and BLK0b in the same memory cell array BLK0 to be in a non-conductive state. Accordingly, in a mode of reading with transition between blocks, it suffices to cause only the switching elements Sa1 to Sa16 that are in a conductive state to be in a non-conductive state. Therefore, power consumption is reduced more as compared with a case of causing all the switching elements Sa1 to Sa16 and Sb1 to Sb16 to be in a non-conductive state.

As described above, current consumption is increased in transition between subblocks in the same memory cell array in the first comparative example. Meanwhile, according to the present embodiment, once the switching elements Sa1 to Sa16 in the subblock BLK0a are placed in a conductive state, the conductive state of the switching elements Sa1 to Sa16 is maintained until transition from the memory cell array BLK0 to the other memory cell array BLK1 occurs, even when the subblock BLK0b is selected. Therefore, power consumption is reduced as compared with that in the first comparative example. Further, current consumption is increased in reading with transition between blocks in the second comparative example, whereas according to the present embodiment, power consumption is reduced as compared with that in the second comparative example because the subblock BLK0a maintains its preceding state when the other subblock BLK0b in the same memory cell array BLK0 is selected. As described above, according to the present embodiment, it is possible to reduce power consumption by improving an operation that causes increase of power consumption in each of the first and second comparative examples.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

1. A semiconductor storage device comprising:
a plurality of memory cell arrays each including a plurality of subblocks connected to each other via common word lines and each including memory cells at respective intersections between the word lines and bit lines provided in each of the subblocks;
a plurality of block selectors each including switching elements connected to bit lines in a corresponding one of the subblocks at one ends, respectively, and to a corresponding sense amplifier at the other ends; and
a controller configured to, in a case where data is read out from one of the subblocks in a same memory cell array and thereafter data is read out from another one of the subblocks in the same memory cell array, maintain the switching elements in one of the block selectors corresponding to the one subblock in a conductive state.

2. The device of claim 1, wherein in a case where data is read out from one of the subblocks in the memory cell array, the controller maintains the switching elements in one of the block selectors corresponding to another subblock in the same memory cell array in a non-conductive state when the switching elements are already in the non-conductive state.

3. The device of claim 1, wherein in a case where switching elements in all block selectors that correspond to the subblocks in the same memory cell array are in a non-conductive state and data is read out via one of all the block selectors, the controller causes only switching elements in the one block selector to be in a conductive state.

4. The device of claim 1, wherein in a case where data is read out from another memory cell array, the controller causes switching elements that are in a conductive state in all block selectors corresponding to the subblocks in the same memory cell array to be in a non-conductive state.

5. The device of claim 1, wherein in a case where data is read out from one of the memory cell arrays, the controller causes the switching elements in one of the block selectors which corresponds to another one of the memory cell arrays to be in a non-conductive state.

6. The device of claim 1, wherein
the controller includes a logic circuit, and
the logic circuit outputs a first signal that causes switching elements in one of the block selectors which corresponds to a different memory cell array from the memory cell array including a selected subblock to be in a non-conductive state.

7. The device of claim 6, wherein the logic circuit outputs a second signal that maintains a state of switching elements in a block selector corresponding to another subblock in the memory cell array including the selected subblock.

8. The device of claim 7, wherein the logic circuit outputs a third signal that causes switching elements in a block selector corresponding to the selected subblock to be in a conductive state.

9. A semiconductor storage device comprising:
a first memory cell array including a first subblock and a second subblock connected to each other via common word lines and each including memory cells at respective intersections between the word lines and bit lines in each of the first subblock and the second subblock;
a second memory cell array including a third subblock and a fourth subblock connected to each other via common word lines and each including memory cells at respective intersections between the word lines and bit lines in each of the third subblock and the fourth subblock;
a first block selector including switching elements that are connected to the bit lines in the first subblock at one ends, respectively, and to a corresponding sense amplifier at the other ends;
a second block selector including switching elements that are connected to the bit lines in the second subblock at one ends, respectively, and to a corresponding sense amplifier at the other ends;
a third block selector including switching elements that are connected to the bit lines in the third subblock at one ends, respectively, and to a corresponding sense amplifier at the other ends;
a fourth block selector including switching elements that are connected to the bit lines in the fourth subblock at one ends, respectively, and to a corresponding sense amplifier at the other ends; and
a controller configured to, in a case where data is read out from one of the first memory cell array and the second memory cell array and thereafter data is read from the other, maintain the switching elements in one of the first block selector and the second block selector which corresponds to the one memory cell array.

10. A control method of a semiconductor storage device including
a plurality of memory cell arrays that each include a plurality of subblocks connected to each other via common word lines and that include memory cells at respective intersections between the word lines and bit lines provided in each of the subblocks, and
a plurality of block selectors each including switching elements that are connected to bit lines in a corresponding one of the subblocks at one ends and to a corresponding sense amplifier at the other ends, the method comprising,
in a case where data is read out from one subblock in the same memory cell array and thereafter data is read out from another subblock in the same memory cell array, maintaining the switching elements in a block selector corresponding to the one subblock in a conductive state.

11. The method of claim 10, wherein in a case where data is read out from one of the subblocks in the memory cell array, the switching elements in one of the block selectors corresponding to another subblock in the same memory cell array is maintained in a non-conductive state when the switching elements are already in the non-conductive state.

12. The method of claim 10, wherein in a case where switching elements in all block selectors that correspond to the subblocks in the same memory cell array are in a non-conductive state and data is read out via one of all the block selectors, only switching elements in the one block selector are caused to be in a conductive state.

13. The method of claim 10, wherein in a case where data is read out from another memory cell array, switching elements that are in a conductive state in all block selectors corresponding to the subblocks in the same memory cell array are caused to be in a non-conductive state.

14. The method of claim 10, wherein in a case where data is read out from one of the memory cell arrays, the switching elements in one of the block selectors which corresponds to another one of the memory cell arrays are caused to be in a non-conductive state.

15. The method of claim 10, wherein a first signal that causes switching elements in one of the block selectors which corresponds to a different memory cell array from the memory cell array including a selected subblock to be in a non-conductive state is output.

16. The method of claim 15, wherein a second signal that maintains a state of switching elements in a block selector corresponding to another subblock in the memory cell array including the selected subblock is output.

17. The method of claim 15, wherein a third signal that causes switching elements in a block selector corresponding to the selected subblock to be in a conductive state is output.
